(19) United States
(12) Patent Application Publication
(10) Pub. No.: US 2022/0368101 A1
(43) Pub. Date: Nov. 17, 2022

(54) WAVELENGTH CONVERSION ELEMENT

(71) Applicant: SONY GROUP CORPORATION, Tokyo (JP)

(72) Inventors: Izushi KOBAYASHI, Tokyo (JP); Yuki MAEDA, Tokyo (JP)

(73) Assignee: SONY GROUP CORPORATION, Tokyo (JP)

(21) Appl. No.: 17/623,945

(22) PCT Filed: Jun. 11, 2020
(86) PCT No.: PCT/JP2020/022966

§ 371 Date: Dec. 30, 2021

(30) Foreign Application Priority Data
Jul. 9, 2019 (JP) 2019-127473

(51) Int. Cl. H01S 5/024; H01S 5/026; G02B 3/08; G02B 5/20

(52) U.S. Cl. CPC H01S 5/02423; H01S 5/0267; G02B 3/08; G02B 5/206; B82Y 20/00

(57) ABSTRACT

A wavelength conversion element according to an embodiment of the present disclosure includes: a phosphor layer including a plurality of phosphor particles; a refrigerant that cools the phosphor layer; a storage section that stores the phosphor layer and the refrigerant; and a light-transmissive section that seals the storage section in combination with the storage section, and controls an output direction of output light outputted from the phosphor layer.

### TECHNICAL FIELD

The present disclosure relates to a wavelength conversion element including a phosphor particle.

### BACKGROUND ART

In laser excitation phosphor light sources using a two-phase cooling technique, flat-shaped cover glass is used on the output side of a sealed housing (e.g., see PTL 1).

### CITATION LIST

### Patent Literature

PTL 1: Japanese Unexamined Patent Application Publication No. 2016-225148

### SUMMARY OF THE INVENTION

Incidentally, a laser excitation phosphor light source is requested to increase light utilization efficiency.

It is desirable to provide a wavelength conversion element that makes it possible to increase light utilization efficiency.

A wavelength conversion element according to an embodiment of the present disclosure includes: a phosphor layer including a plurality of phosphor particles; a refrigerant that cools the phosphor layer; a storage section that stores the phosphor layer and the refrigerant; and a light-transmissive section that seals the storage section in combination with the storage section, and controls an output direction of output light outputted from the phosphor layer.

In the wavelength conversion element according to the embodiment of the present disclosure, the phosphor layer and the refrigerant are encapsulated by using the storage section, and the light-transmissive section that controls the output direction of the output light outputted from the phosphor layer. This extracts output light with a small etendue.

### BRIEF DESCRIPTION OF DRAWING

FIG. 1 is a cross-sectional schematic diagram illustrating an example of a configuration of a wavelength conversion element according to an embodiment of the present disclosure.

FIG. 2 is a plane schematic diagram of the wavelength conversion element illustrated in FIG. 1.

FIG. 3 is a cross-sectional schematic diagram illustrating a joint surface between a phosphor layer and a light-transmissive section.

FIG. 4 is a cross-sectional schematic diagram illustrating another example of the configuration of the wavelength conversion element according to the embodiment of the present disclosure.

FIG. 5 is a flowchart of steps of manufacturing the phosphor layer.

FIG. 6 is a cross-sectional schematic diagram illustrating an example of a configuration of a wavelength conversion element according to a modification example 1 of the present disclosure.

FIG. 7 is a cross-sectional schematic diagram illustrating an example of a configuration of a wavelength conversion element according to a modification example 2 of the present disclosure.

FIG. 8 is a cross-sectional schematic diagram illustrating an example of a configuration of a wavelength conversion element according to a modification example 3 of the present disclosure.

FIG. 9 is a cross-sectional schematic diagram illustrating an example of a configuration of a wavelength conversion element according to a modification example 4 of the present disclosure.

FIG. 10 is a cross-sectional schematic diagram illustrating an example of a configuration of a wavelength conversion element according to a modification example 5 of the present disclosure.

FIG. 11 is a plane schematic diagram illustrating an example of a planar configuration of a refrigerant transport member illustrated in FIG. 10.

FIG. 12 is a cross-sectional schematic diagram illustrating an example of a configuration of a wavelength conversion element according to a modification example 6 of the present disclosure.

FIG. 13 is a cross-sectional schematic diagram illustrating an example of a configuration of a wavelength conversion element according to a modification example 7 of the present disclosure.

FIG. 14 is a plane schematic diagram of the wavelength conversion element illustrated in FIG. 13.

FIG. 15 is a cross-sectional schematic diagram illustrating another example of the configuration of the wavelength conversion element according to the modification example 7 of the present disclosure.

FIG. 16 is an outline diagram illustrating an example of a configuration of a light source module including the wavelength conversion element illustrated in FIG. 1 or the like.

FIG. 17 is an outline diagram illustrating another example of the configuration of the light source module including the wavelength conversion element illustrated in FIG. 1 or the like.

FIG. 18 is an outline diagram illustrating an example of a configuration of a projector including the light source module illustrated in FIG. 16 or the like.

FIG. 19 is an outline diagram illustrating another example of the configuration of the projector including the light source module illustrated in FIG. 16 or the like.

### MODES FOR CARRYING OUT THE INVENTION

The following describes embodiments of the present disclosure in detail with reference to the drawings. The following description is a specific example of the present disclosure, but the present disclosure is not limited to the following modes. In addition, the present disclosure is not also limited to the disposition, dimensions, dimension ratios, and the like of the respective components illustrated in the respective diagrams. It is to be noted that description is given in the following order.

1. Embodiment (Example in which front part of housing includes light-transmissive section having lens function)

### 1-1. Configuration of Wavelength Conversion Element

### 1-2. Workings and Effects

### 2. Modification Examples

2-1. Modification Example 1 (Example in which substantially flat-shaped member is used as light-transmissive section)
2-2. Modification Example 2 (Example in which bottom surface of storage section serves as reflection surface)
2-3. Modification Example 3 (Example in which phosphor layer has layered structure)
2-4. Modification Example 4 (Example in which portion of surface of light-transmitting section serves as reflection surface)
2-5. Modification Example 5 (Example in which flow paths for refrigerant transport are provided on surface of refrigerant transport member)
2-6. Modification Example 6 (Example of transmissive wavelength conversion element)
2-7. Modification Example 7 (Example of rotary wavelength conversion element)
3. Application Example (Examples of light source module and projector)

### 1. Embodiment

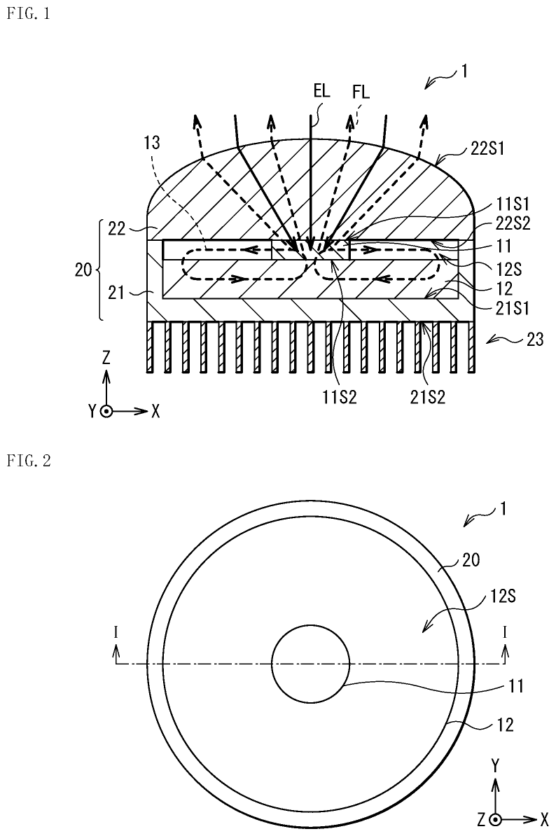

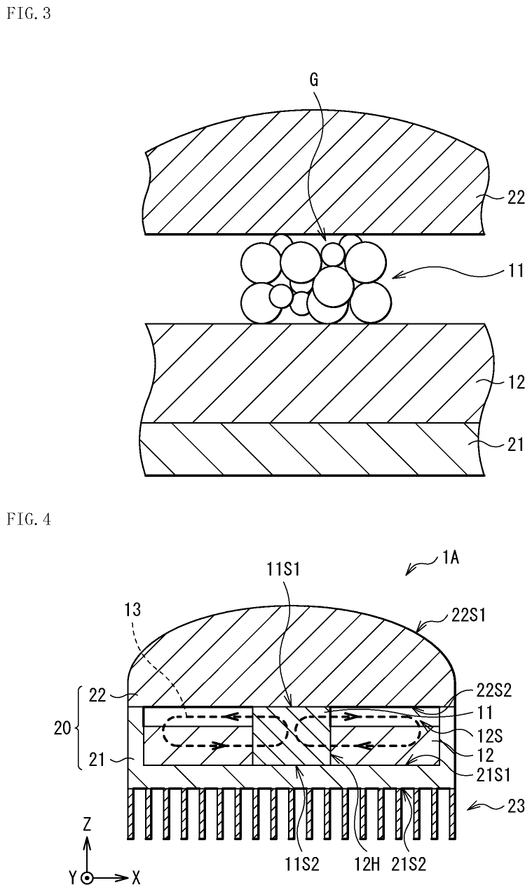

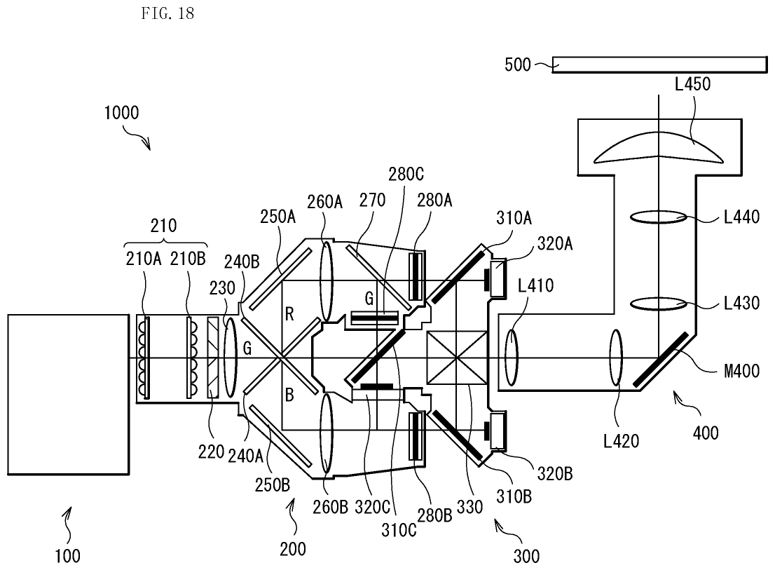

FIG. 1 schematically illustrates an example of a cross-sectional configuration of a wavelength conversion element (wavelength conversion element 1) according to an embodiment of the present disclosure. FIG. 2 schematically illustrates a planar configuration of the wavelength conversion element 1 illustrated in FIG. 1. FIG. 1 illustrates a cross-section taken along an I-I line illustrated in FIG. 2. This wavelength conversion element 1 is included, for example, in a light source module (light source module 100) of a projection display apparatus (projector 1000) described below (e.g., see FIGS. 16 and 18). The wavelength conversion element 1 has a configuration in which a phosphor layer 11 and a refrigerant transport member 12 are encapsulated in a housing 20 along with a refrigerant 13. The phosphor layer 11 and the refrigerant transport member 12 are stacked together. The phosphor layer 11 is directly cooled by the evaporative latent heat of the refrigerant 13.

### 1-1. Configuration of Wavelength Conversion Element

The wavelength conversion element 1 has a so-called two-phase cooling structure in which, as described above, the phosphor layer 11 encapsulated in the housing 20 is directly cooled by the evaporative latent heat of the refrigerant 13 that circulates in the housing 20. The housing 20 according to the present embodiment includes, for example, a storage section 21 and a light-transmissive section 22. The light-transmissive section 22 seals the internal space of the storage section 21 in combination with the storage section 21. The light-transmissive section 22 controls an output direction of output light (fluorescent light FL) outputted from the phosphor layer 11.

The phosphor layer 11 includes a plurality of phosphor particles. It is preferable that the phosphor layer 11 be formed, for example, as an open-cell porous layer. Although described in detail below, it is preferable that the size (average pore size) of the pores (gaps) be smaller than the average pore size of the refrigerant transport member 12 that is also formed as an open-cell porous layer. For example, an average pore size of 30 μm or less is preferable. It is preferable that the phosphor layer 11 be formed, for example, to have a plate shape or a cylindrical shape. The phosphor layer 11 includes, for example, so-called ceramic phosphors or binder-type porous phosphors.

Each of the phosphor particles is a particle-shaped phosphor that absorbs excitation light EL radiated from a light source section 110 described below to emit fluorescent light FL. For example, as a phosphor particle, a fluorescent substance is used that is excited by blue laser light having a wavelength in the blue wavelength range (e.g., 400 nm to 470 nm) to emit yellow fluorescent light (light in a wavelength range between the red wavelength range and the green wavelength range). Examples of such a fluorescent substance include an YAG (yttrium/aluminum/garnet)-based material and an LAG (lutetium/aluminum/garnet)-based material. For example, phosphor particles have an average particle size of 10 μm or more and 100 μm or less.

It is preferable that the phosphor layer 11 have a smaller diameter, for example, than that of the refrigerant transport member 12 and have a space (space 12S) between a side surface of the phosphor layer 11 and the side wall of the housing 20 (storage section 21). This efficiently circulates the refrigerant 13 in a cooling cycle of the wavelength conversion element 1 described below.

Further, it is preferable that the phosphor layer 11 be disposed, in the housing 20, to be opposed to the light-transmissive section 22 that transmits the excitation light EL and the fluorescent light FL. In addition, it is desirable that a surface 11S1 of the phosphor layer 11 be in contact with a surface 22S2 of the light-transmissive section 22. This makes it possible to prevent a droplet from adhering to the surface 22S2 of the light-transmissive section 22 right opposed to the phosphor layer 11 and prevent the excitation light EL and the fluorescent light FL from being scattered by the droplet.

It is to be noted that, in a typical wavelength conversion element, it is desirable that a light emitting section of a phosphor layer be in contact with a front part of a housing from which fluorescent light FL is outputted. However, in the wavelength conversion element 1 according to the present embodiment, for example, a gap G may be present partly between the phosphor layer 11 and the light-transmissive section 22, as illustrated in FIG. 3, for the following reason. In the wavelength conversion element 1 according to the present embodiment, the fluorescent light FL outputted from the phosphor layer 11 is immediately inputted to the light-transmissive section 22 having a lens function. This makes it possible to suppress light extraction loss due to scattering of the fluorescent light FL caused by a droplet adhering to the surface 22S2 of the light-transmissive section 22 opposed to the phosphor layer 11.

It is to be noted that FIG. 1 illustrates the example in which the phosphor layer 11 is stacked on the refrigerant transport member 12, but this is not limitative. For example, as with a wavelength conversion element 1A illustrated in FIG. 4, there may be provided an opening 12H to the refrigerant transport member 12 and the opening 12H may be filled with the phosphor layer 11. The opening 12H has substantially the same diameter as the outer shape of the phosphor layer 11. In that case, a surface 11S2 of the phosphor layer 11 on the storage section 21 side may be in contact with or bonded to the bottom surface (surface 21S) of the storage section 21, as with the surface 11S1.

The refrigerant transport member 12 is for carrying the refrigerant 13 to the phosphor layer 11. It is preferable that the refrigerant transport member 12 be formed as an open-cell porous layer as with the phosphor layer 11. It is preferable that the average pore size of the refrigerant transport member 12 be greater than the average pore size of the phosphor layer 11.

The wavelength conversion element 1 according to the present embodiment is a so-called reflective wavelength conversion element that extracts the fluorescent light FL by reflecting the fluorescent light FL, for example, in the same direction as the direction in which the excitation light EL is inputted. The fluorescent light FL is emitted from the phosphor layer 11 irradiated with the excitation light EL. It is therefore preferable that the refrigerant transport member 12 further have a light scattering property (light reflectivity). For example, the use of an inorganic material such as a metal material or a ceramic material is preferable.

Examples of a material included in the refrigerant transport member 12 include a single metal such as aluminum (Al), copper (Cu), molybdenum (Mo), tungsten (W), cobalt (Co), chromium (Cr), platinum (Pt), tantalum (Ta), lithium (Li), zirconium (Zr), ruthenium (Ru), rhodium (Rh), or palladium (Pd) or an alloy including one or more of these. In addition, an oxide such as titanium oxide (TiO₂), zirconium oxide (ZrO₂), barium sulfate (BaSO₄), or silicon oxide (SiO₂) may be used. In addition, diamond may be used. The refrigerant transport member 12 includes a sintered ceramic compact, a sintered metal, or a porous metal including, for example, the material described above.

For example, as indicated by arrows illustrated in FIG. 1, the refrigerant 13 circulates between the phosphor layer 11 and the refrigerant transport member 12 to cool the phosphor particles heated by being irradiated with the excitation light EL. For example, it is preferable that a liquid having great latent heat be used for the refrigerant 13. In addition, the refrigerant 13 circulates through gaps formed in the phosphor layer 11 and the refrigerant transport member 12. It is therefore preferable that the refrigerant 13 have low viscosity. Specific examples of the refrigerant 13 include water, acetone, methanol, naphthalin, benzene, and the like.

It is possible to form a sealed space (internal space) in the housing 20. A front part of the housing 20 includes a member having light transmissivity. The front part receives the incident excitation light EL and outputs the fluorescent light FL. The front part of the housing 20 includes the light-transmissive section 22 that controls the output direction of the output light outputted from the phosphor layer 11. The light-transmissive section 22 is bonded to the storage section 21 that stores the phosphor layer 11, the refrigerant transport member 12, and the refrigerant 13.

The light-transmissive section 22 according to the present embodiment includes a light-transmitting member having a lens shape, as illustrated in FIG. 1. Specifically, the light-transmissive section 22 may use a so-called planoconvex lens having one surface that is a spherical surface and another surface, opposed to the one surface, that is a flat surface. In the present embodiment, the surface 22S2 having a planar shape is disposed to be right opposed to the phosphor layer 11, and a surface 22S1 having a spherical surface shape serves as an incidence surface of the excitation light EL and as an output surface of the fluorescent light FL. Thus, the excitation light EL inputted to the light-transmissive section 22 is refracted by the spherical surface (surface 22S1) of the light-transmissive section 22 to be condensed on the phosphor layer 11, as illustrated in FIG. 1. In addition, the fluorescent light FL outputted from the phosphor layer 11 is refracted by the spherical surface (surface 22S1) of the light-transmissive section 22.

As a material included in the housing 20, for example, aluminum, copper, stainless steel, low-carbon steel, an alloy material thereof, and a highly thermally conductive ceramic, such as silicon carbide or aluminum nitride, may be used for the storage section 21. In addition to a glass substrate, for example, soda glass, quartz, sapphire glass, crystal, and the like may be used for the light-transmissive section 22. In addition, in a case where the light source section 110 outputs laser light with low output power, resins and the like may be used such as polyethylene terephthalate (PET), a silicone resin, polycarbonate, and acrylic.

The back surface of the housing 20 (a surface 21S2 of the storage section 21) is further provided with a heat dissipation member 23. The heat dissipation member 23 is for cooling the storage section 21. This condenses the vapor of the refrigerant 13 on the inner surface side of the storage section 21 to bring about a phase change into liquid and the liquid is transported to the phosphor layer 11 by the refrigerant transport member 12. The heat dissipation member 23 may include, for example, a plurality of heat dissipation fins as illustrated in FIG. 1, but this is not limitative. For example, a water cooling system such as a Peltier element or a water cooling plate may be used, for example, as the heat dissipation member 23.

A protective film may be formed on the inner wall that defines the internal space of the housing 20. The protective film is for preventing a foreign object from dissolving in the refrigerant 13 from the storage section 21 (e.g., the elution of metal ions derived from the metal included in the storage section 21) and preventing the metal included in the storage section 21 from corroding. The use of a material having a high affinity with the refrigerant 13 is preferable for a material included in the protective film.

For example, in a case where water is used as the refrigerant 13, a material of the protective film includes an oxide such as silicon oxide (SiO₂), aluminum oxide (Al₂O₃), and titanium oxide (TiO₂) having high hydrophilicity. In addition, a metal material that has, for example, a standard electrode potential of more than 0.35 V and rusts less easily may be used such as gold (Au), silver (Ag), or stainless steel. In that case, it is preferable, for example, to perform plasma processing on the surface and provide the surface of the metal film with hydroxyl groups. This increases the affinity with the refrigerant 13 (e.g., water). Alternatively, the oxide film described above may be formed on the surface of the metal film described above.

Examples of metal materials other than the above include zinc (Zn), nickel (Ni), and chromium (Cr) or an alloy including them. The protective film may be a single layer film or a stacked film. In a case where the protective film is formed as a stacked film, it is preferable, for example, to form the oxide film described above on the outermost layer. It is possible to form the protective film, for example, by vapor deposition, film formation by a sputtering device, coating such as spin coating, plating, or mechanical bonding.

It is to be noted that providing the protective film with a minute (e.g., several μm to several mm) concave and convex structure on the surface also makes it possible to increase the affinity with the refrigerant 13. Providing the surface of the protective film with a concave and convex structure facilitates the refrigerant 13 to enter the surface of the protective film by capillary force as with the refrigerant transport member 12 described above and increases the affinity (wettability). In addition, the protective film may be provided with an optical reflection function, an optical anti-reflection function, a color separation function, a polarization separation function, an optical phase adjustment function, a high thermal conduction function, and the like in addition to a function of protecting the surface of the storage section 21.

As described above, the wavelength conversion element 1 according to the present embodiment has a two-phase cooling structure in which the stacked phosphor layer 11 and refrigerant transport member 12 are encapsulated in the housing 20 along with the refrigerant 13. The housing 20 has a sealed internal space. The phosphor layer 11 is directly cooled by the evaporative latent heat of the refrigerant 13. To circulate the refrigerant 13 from the refrigerant transport member 12 to the phosphor layer 11, it is desirable that the capillary force generated in the phosphor layer be greater than the capillary force generated in the refrigerant transport member 12. The capillary force is expressed by the following expression.

(Expression 1)P=2T cos θ/ρgr (1)

(P represents capillary force, T represents surface tension, θ represents a contact angle, ρ represents the density of liquid, g represents gravitational acceleration, and r represents a capillary radius)

The equivalent capillary radius of the refrigerant transport member 12 is proportional to the average pore size. To cause the phosphor layer 11 to have capillary force greater than the capillary force of the refrigerant transport member 12, it is desirable from the expression (1) described above that the average pore size of the refrigerant transport member 12 be greater than the average pore size of the phosphor layer 11. In addition, as indicated by the expression (1), one of the phosphor layer 11 and the refrigerant transport member 12 that has a smaller contact angle has greater capillary force. It is therefore desirable that materials included in the phosphor layer 11 and the refrigerant transport member 12 each have wettability.

It is to be noted that, in a case where the wavelength conversion element 1 according to the present embodiment stands upright for use, the capillary force of the refrigerant transport member 12 has to draw up the refrigerant 13 to the irradiated position (light emitting section) with the excitation light EL against gravity. Accordingly, in a case where R₀ represents the distance from the light emitting section to the outermost periphery (the inner side surface of the storage section 21), it is desirable that capillary force P of the refrigerant transport member 12 satisfy P≥hydraulic head difference R₀ (mmH₂O). This does not, however, apply in a case where a wavelength conversion element is rotated for use as with a wavelength conversion element 1D described below.

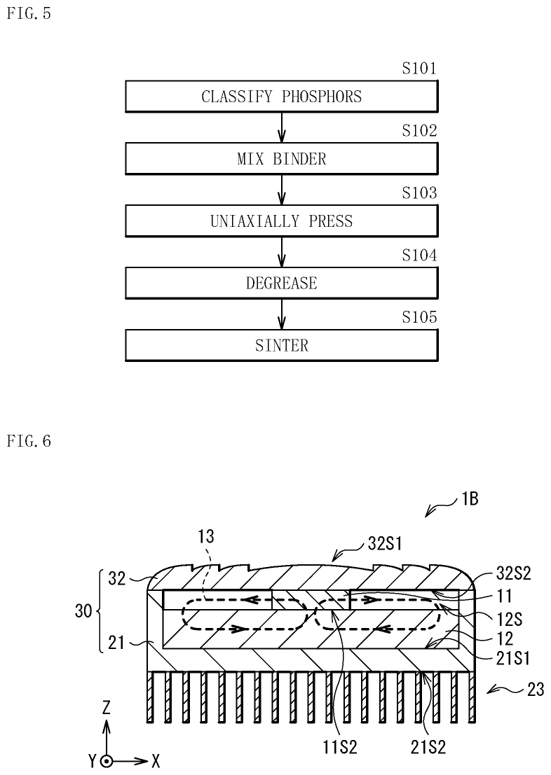

In a case where the phosphor layer 11 and the refrigerant transport member 12 are each formed by using a sintered compact, control over predetermined parameters in the manufacturing steps of each of the sintered compacts offers a desired average pore size. The following gives description by using a sintered phosphor as an example. FIG. 5 is a flowchart of steps of manufacturing a sintered phosphor.

First, phosphors are classified to control the particle size of the phosphor particles (step S101). The phosphor particles and a binder are then mixed together (step S102). Next, the pressing pressure is controlled to perform uniaxial press (step S103). Subsequently, degreasing is performed (step S104) and sintering is then performed (step S105). As described above, the phosphor layer 11 including sintered phosphors is formed. It is possible to adjust the average pore size of the sintered phosphors at a desired value by classifying phosphors in step S101, controlling the pressing pressure for uniaxial press in step S103, and controlling the sintering temperature in step S105.

The cooling cycle of the wavelength conversion element 1 according to the present embodiment is described.

First, in a case where the phosphor layer 11 is irradiated with the excitation light EL, the phosphor particles generate heat. The refrigerant 13 is evaporated by that heat and concurrently takes the latent heat away. In a case where the middle portion of the phosphor layer 11 is irradiated with the excitation light EL as illustrated in FIG. 1, the evaporated refrigerant 13 moves to the space 12S on the outer peripheral side of the phosphor layer 11 as vapor. The vapor that has moved to the space 12S dissipates the latent heat through the inner wall of the storage section 21 and is liquidized again. The liquidized refrigerant 13 is transported to the phosphor layer 11 by the capillary force of the refrigerant transport member 12 and moved to the heated section of the phosphor layer 11 by the capillary force of the phosphor layer 11. The heat generated through the radiation of the excitation light EL is discharged to the refrigerant transport member 12 by repeating this.

### 1-2. Workings and Effects

The wavelength conversion element 1 according to the present embodiment uses the light-transmissive section 22 having a lens shape and configured to control the output direction of the fluorescent light FL, as the front part of the housing 20 that is sealed to encapsulate the phosphor layer 11, the refrigerant transport member 12, and the refrigerant 13. The front part serves as the output surface from which the fluorescent light FL emitted from the phosphor layer 11 is outputted. This narrows an output angle of the fluorescent light FL to be outputted from the output surface of the housing 20, making it possible to extract the fluorescent light FL with a low etendue. This is described below.

In recent years, laser excitation phosphors have been used as light sources in projection display apparatuses (projectors). The laser excitation phosphor light sources have an issue with an increase in the cooling efficiency of phosphors. The two-phase cooling technique (phase change cooling technique) that uses latent heat has attracted attention. This two-phase cooling technique allows a refrigerant to directly cool a light emitting particle of a phosphor or a light emitting region.

However, in a configuration using a typical two-phase cooling technique, an output surface of fluorescent light includes flat-shaped cover glass. By a coolant adhering to the cover glass, a portion of the fluorescent light is reflected a plurality of times in the cover glass, which can cause light extraction efficiency to decrease. In addition, an etendue (light emission size×light emission solid angle) of fluorescent light emission also increases, which can cause utilization efficiency of the fluorescent light to decrease.

In contrast, in the present embodiment, the output surface, of the fluorescent light FL emitted from the phosphor layer 11, of the housing 20 includes the light-transmissive section 22 having a lens shape, for example, and configured to control the output direction of the fluorescent light FL. Thus, the fluorescent light FL emitted from the phosphor layer 11 is refracted by the lens surface (surface 22S1) of the light-transmissive section 22, which narrows the output angle. This makes it possible to enhance extraction efficiency of the fluorescent light FL, and to extract the fluorescent light FL with a small etendue.

As described above, in the wavelength conversion element 1 according to the present embodiment, the output surface of the fluorescent light FL includes the light-transmissive section 22 having a lens shape. Thus, the fluorescent light FL is refracted by the lens surface (surface 22S1) of the light-transmissive section 22 to be outputted. This reduces the etendue of the fluorescent light FL to be outputted from the wavelength conversion element 1, making it possible to increase light utilization efficiency.

In addition, the wavelength conversion element 1 according to the present embodiment uses a two-phase cooling technique. This makes it possible to keep the phosphor layer 11 at constant temperature. This makes it possible in the light source module including this wavelength conversion element 1 to stabilize the light source output power and allows a projector including this to have higher image quality.

Further, in the present embodiment, the phosphor layer 11 and the light-transmissive section 22 are in contact with each other, which prevents a droplet from adhering to the surface 22S2 of the light-transmissive section 22 opposed to the phosphor layer 11. This reduces scattering of the fluorescent light FL caused by the droplet, which makes it possible to reduce a decrease in the light extraction efficiency due to reflection of the fluorescent light FL in the light-transmissive section 22. This makes it possible to further increase the light utilization efficiency.

Still further, in the present embodiment, the front part includes the light-transmissive section 22 configured to control the output direction of the fluorescent light FL, as described above. Thus, even if the gap G is formed between the phosphor layer 11 and the light-transmissive section 22, as illustrated in FIG. 3, it is possible to reduce a decrease in the light extraction efficiency, as compared with a typical wavelength conversion element.

In addition, it is possible in the present embodiment to achieve a non-rotary wavelength conversion element that has highly efficient cooling performance and allows for stable use. This makes it possible to miniaturize the light source module and the projector. Further, there is less concern about image quality deterioration caused by rotation flicker as compared with the use of a rotary wavelength conversion element. It is therefore possible to further stabilize the light source output power. In addition, it is also possible to further increase the image quality of the projector including this.

Next, modification examples 1 to 7 and an application example are described. The following assigns the same signs to components similar to those of the embodiment described above and omits descriptions thereof as appropriate.

### 2. Modification Examples

### 2-1. Modification Example 1

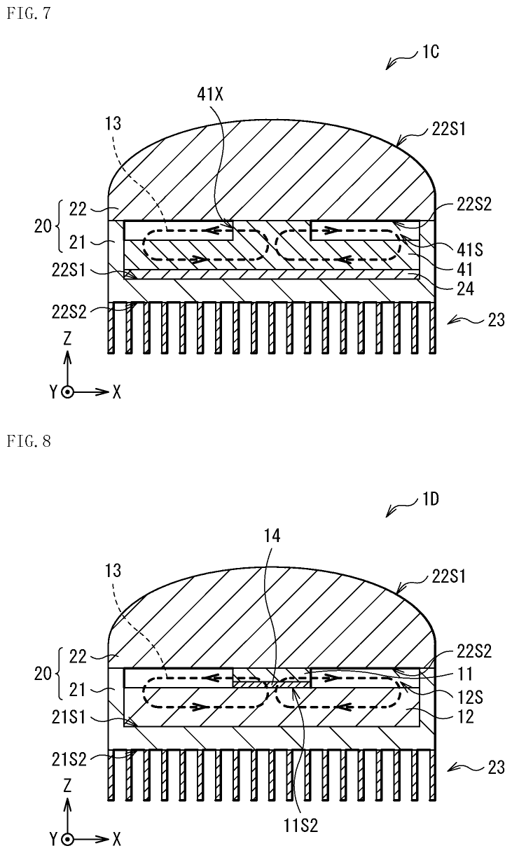

FIG. 6 schematically illustrates an example of a cross-sectional configuration of a wavelength conversion element (wavelength conversion element 1B) according to a modification example 1 of the present disclosure. As with the embodiment described above, this wavelength conversion element 1B is included in the light source module (light source module 100) of the projection display apparatus (projector 1000). The wavelength conversion element 1B according to the present modification example encapsulates the stacked phosphor layer 11 and refrigerant transport member 12 in a housing 30 along with the refrigerant 13, and is different from the embodiment described above in that a light-transmissive section 32 included in a front part of the housing 30 includes a substantially flat-shaped light-transmitting member.

The light-transmissive section 32 controls the output direction of the output light outputted from the phosphor layer 11. The light-transmissive section 32 includes a substantially flat-shaped light-transmitting member, as described above. Specifically, the light-transmissive section 22 may use a Fresnel lens or a meta-surface (meta-lens) having a nanoscale structure as an output surface (surface 32S1). It is to be noted that a surface (surface 32S2) right opposed to the phosphor layer 11 has a planar shape, for example, as with the light-transmissive section 22 according to the embodiment described above.

As described above, the wavelength conversion element 1B according to the present modification example uses, as the light-transmissive section 32, a Fresnel lens or a meta-lens whose output surface (surface 32S1) is substantially flat-shaped. This makes it possible to reduce a thickness in a Z-axis direction, as compared with the wavelength conversion element 1 (1A) according to the embodiment described above. Thus, in addition to the effect according to the embodiment described above, it is possible to miniaturize (thin down) the wavelength conversion element.

### 2-2. Modification Example 2

FIG. 7 schematically illustrates an example of a cross-sectional configuration of a wavelength conversion element (wavelength conversion element 1C) according to a modification example 2 of the present disclosure. As with the embodiment described above, this wavelength conversion element 1C is included in the light source module (light source module 100) of the projection display apparatus (projector 1000). The wavelength conversion element 1C according to the present modification example is different from the embodiment described above in that a reflective film 24 is provided on the opposite surface (surface 21S1), of the internal space of the housing 20, to the light-transmissive section 22 side. The housing 20 stores a phosphor layer 41 and the refrigerant 13.

It is preferable that the reflective film 24 highly efficiently reflect an emission wavelength (the fluorescent light FL) of the phosphor and a wavelength of the excitation light EL, for example. Such a reflective film 24 may include, for example, a silver mirror, an aluminum high reflection coating, a dielectric multilayer coating, or the like.

In addition, in a case where the reflective film 24 is provided on the storage section 21 side of the phosphor layer 11, as with the present modification example, the phosphor layer 41 may serve also as the refrigerant transport member 12. That is, it is preferable that the phosphor layer 41 have, for example, substantially the same outer shape as the internal space of the housing 20, and have a shape with a protrusion 41X at the position to be irradiated with the excitation light EL (i.e., the light emitting section), as illustrated in FIG. 7. Thus, the refrigerant 13 flows through a portion of the phosphor layer 41 having substantially the same outer shape as the internal space to directly cool the light emitting section (the protrusion 41X) by latent heat, and the evaporated refrigerant 13 moves to a space 41S around the protrusion 41X as vapor and is liquidized again.

As described above, in the present modification example, the reflective film 24 is provided on the opposite surface (surface 21S1), of the internal space of the housing 20, to the light-transmissive section 22 side, to make the bottom surface of the storage section 21 serve as a reflection surface. This makes it possible to further increase the utilization efficiency of the fluorescent light FL and the excitation light EL, as compared with the wavelength conversion element 1 (1A) according to the embodiment described above. That is, it is possible to further increase fluorescent light output power of the light source module 100 described below.

### 2-3. Modification Example 3

FIG. 8 schematically illustrates an example of a cross-sectional configuration of a wavelength conversion element (wavelength conversion element 1D) according to a modification example 3 of the present disclosure. As with the embodiment described above, this wavelength conversion element 1D is included in the light source module (light source module 100) of the projection display apparatus (projector 1000). The wavelength conversion element 1D according to the present modification example encapsulates phosphor layers 11 and 14 and the refrigerant transport member 12 in the housing 20 along with the refrigerant 13, and is different from the embodiment described above in that the phosphor layer has a layered structure (e.g., a two-layer structure of the phosphor layer 11 and the phosphor layer 14).

In the present modification example, as the phosphor layer, the phosphor layer 11 and the phosphor layer 14 are stacked in this order from the light-transmissive section 22 side.

The phosphor layer 14 is excited by the light emitted from the phosphor layer 11 and the excitation light EL transmitted through the phosphor layer 11. It is desirable that a peak emission wavelength of the phosphor layer 14 be on a longer wavelength side than a peak emission wavelength of the phosphor layer 11. As a material included in such a phosphor layer 14, it is possible to use a phosphor or a quantum dot having a red emission wavelength, for example, in a case of forming the phosphor layer 11 using an YAG (yttrium/aluminum/garnet)-based material or an LAG (lutetium/aluminum/garnet)-based material.

It is preferable that the phosphor layer 14 be formed, for example, as an open-cell porous layer, as with the phosphor layer 11. It is preferable that the size (average pore size) of the pores (gaps) be, for example, smaller than the average pore size of the refrigerant transport member 12 that is also formed as an open-cell porous layer, and be larger than the average pore size of the phosphor layer 11. This enables the refrigerant 13 to circulate from the phosphor layer 14 to the phosphor layer 11.

It is to be noted that, in a case of using a quantum dot as the material included in the phosphor layer 14, for example, it is desirable that an inorganic capsule be formed by using silicon oxide (SiO₂), aluminum oxide (Al₂O₃), or the like. This reduces deterioration due to the refrigerant 13 (e.g., water).

In addition, a phosphor particle to be used for the phosphor layer 11 and the phosphor layer 14 may be mixed to be formed as a single layer, as with the phosphor layer 11 according to the embodiment described above. Further, although the phosphor layer has the two-layer structure of the phosphor layer 11 and the phosphor layer 14 in the present modification example, the phosphor layer may have a multilayer structure of three layers or four or more layers.

As described above, in the wavelength conversion element 1D according to the present modification example, the phosphor layer has the stacked structure of the phosphor layer 11 and the phosphor layer 14 with the peak emission wavelengths different from each other, which makes it possible to adjust a spectrum of fluorescent light emission as appropriate. This makes it possible to provide the projection display apparatus (projector 1000) configured to project an image with a wide color gamut, in addition to the effect according to the embodiment described above.

In addition, in a case where the wavelength conversion element 1D according to the present modification example is used as an illumination light source, it is possible to increase a color rendering property.

### 2-4. Modification Example 4

FIG. 9 schematically illustrates an example of a cross-sectional configuration of a wavelength conversion element (wavelength conversion element 1E) according to a modification example 4 of the present disclosure. As with the embodiment described above, this wavelength conversion element 1E is included in the light source module (light source module 100) of the projection display apparatus (projector 1000). The wavelength conversion element 1E according to the present modification example encapsulates the stacked phosphor layer 11 and refrigerant transport member 12 in the housing 20 along with the refrigerant 13, and is different from the embodiment described above in that a portion (e.g., a periphery) of the output surface (surface 22S1) of the light-transmissive section 22 included in the front part of the housing 20 serves as a reflection surface.

It is possible to achieve the reflection surface described above by, for example, forming a reflective film 25 on the periphery of the light-transmissive section 22. The reflective film 25 may include, for example, a silver mirror, an aluminum high reflection coating, a dielectric multilayer coating, or the like, as with the reflective film 24 according to the modification example 2 described above. Thus, of the fluorescent light FL emitted from the phosphor layer 11 and outputted toward the light-transmissive section 22, fluorescent light FLx with a large output angle is reflected by the reflective film 25, as illustrated in FIG. 9. The fluorescent light FLx reflected by the reflective film 25 returns to the phosphor layer 11 to be scattered, thereby being outputted from the output surface (surface 22S1), of the light-transmissive section 22, not provided with the reflective film 25.

As described above, in the wavelength conversion element 1E according to the present modification example, the reflective film 25 is provided on the periphery of the light-transmissive section 22 to restrict the output surface from which the fluorescent light FL is extracted. This makes it possible to obtain the fluorescent light FL with a smaller etendue, as compared with the wavelength conversion element 1 (1A) according to the embodiment described above. This makes it possible to further increase the light utilization efficiency.

### 2-5. Modification Example 5

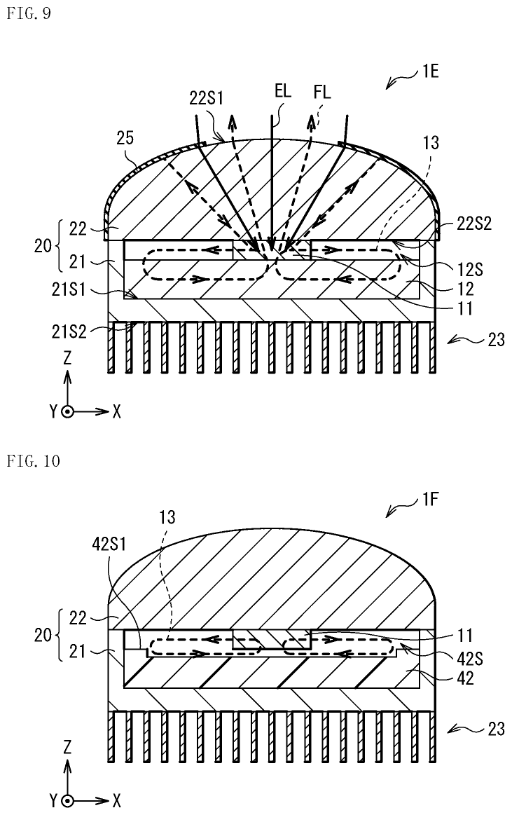

FIG. 10 schematically illustrates an example of a cross-sectional configuration of a wavelength conversion element (wavelength conversion element 1F) according to a modification example 5 of the present disclosure. FIG. 11 schematically illustrates an example of a planar configuration of a refrigerant transport member 42 illustrated in FIG. 10. FIG. 10 illustrates a cross-sectional configuration taken along an II-II line illustrated in FIG. 11. As with the embodiment described above, this wavelength conversion element 1F is included in the light source module (light source module 100) of the projection display apparatus (projector 1000). The wavelength conversion element 1F according to the present modification example encapsulates the stacked phosphor layer 11 and refrigerant transport member 42 in the housing 20 along with the refrigerant 13 and is different from the embodiment described above in that the refrigerant transport member 42 includes a metal plate having minute flow paths 42X formed on the contact surface (surface 42S1) with the phosphor layer 11.

The refrigerant transport member 42 is for carrying the refrigerant 13 to the phosphor layer 11. As described above, the refrigerant transport member 42 has the minute flow paths 42X formed on the contact surface (surface 42S1) with the phosphor layer 11. Grooves are formed through micromachining on the surface 42S1 of the refrigerant transport member 42 as the flow paths 42X. The grooves radially extend from the middle to the outer periphery of the refrigerant transport member 42, for example, as illustrated in FIG. 11. Each of these flow paths 42X is formed, for example, to have both a width and a depth of several tens of μm to several hundreds of μm. This generates capillary force.

It is to be noted that the flow paths 42X are formed to cause the refrigerant transport member 42 to have less capillary force than the capillary force of the phosphor layer 11 as with the first embodiment described above. In addition, FIG. 11 illustrates the example of the flow paths 42X radially extending from the middle to the outer periphery of the refrigerant transport member 42, but this is not limitative. For example, the flow paths 42X may be formed to have a lattice shape or a spiral shape.

It is preferable that a material having high wettability and hydrophilicity be used for a metal plate included in the refrigerant transport member 42. In addition, in a case where use as a light reflecting layer is taken into consideration, for example, the use of an aluminum (Al) substrate is preferable. In addition, it is possible to use a substrate such as a copper (Cu) substrate including an inorganic material mentioned as the above-described material included in the refrigerant transport member 12, but it is preferable in this case that a high-reflective film be formed on the surface.

As described above, the use of a metal plate including the flow paths 42X each having a predetermined size on the (surface 42S1) with the phosphor layer 11 as the refrigerant transport member 42 also makes it possible to obtain an effect similar to that of the embodiment described above.

It is to be noted that the flow paths 42X may also be formed directly on the storage section 21. In that case, it is possible to omit the refrigerant transport member 42. This makes it possible to reduce members included in the wavelength conversion element 1F and miniaturize (thin down) the wavelength conversion element 1F.

### 2-6. Modification Example 6

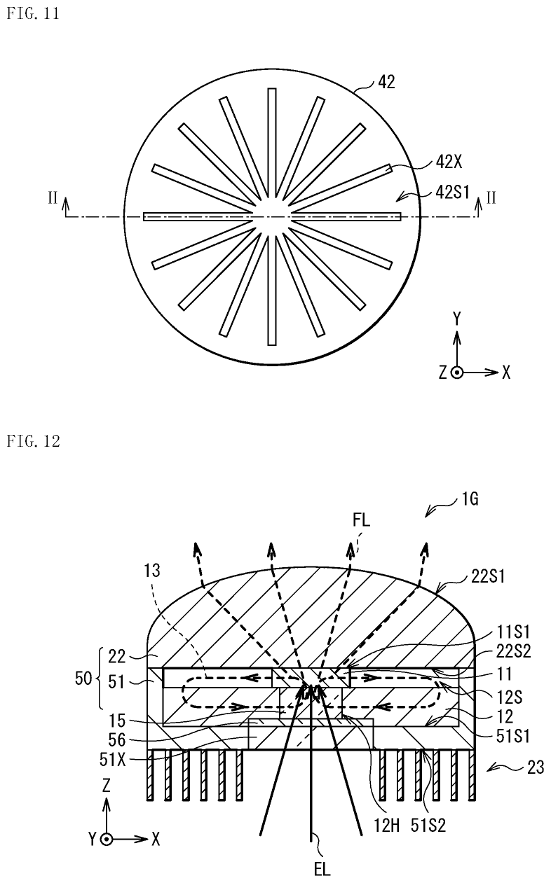

FIG. 12 schematically illustrates a cross-sectional configuration of a wavelength conversion element (wavelength conversion element 1G) according to a modification example 6 of the present disclosure. As with the embodiment described above, this wavelength conversion element 1G is included in the light source module (light source module 100) of the projection display apparatus (projector 1000). The wavelength conversion element 1G according to the present modification example is a so-called transmissive wavelength conversion element in which the fluorescent light FL emitted from the phosphor layer 11 is extracted from the opposite surface to the surface irradiated with the excitation light EL.

The wavelength conversion element 1G according to the present modification example has a configuration in which the excitation light EL is inputted from the back surface (surface 51S2) side of a housing 50, and the fluorescent light FL is outputted from the front surface (surface 22S1) side of the housing 50. Therefore, at least a portion of a storage section 51 included in a back part of the housing 50 preferably has light transmissivity, and includes a light-transmissive section 51X in the present modification example. In addition, for example, it is preferable that an optical thin film 56 that transmits the excitation light EL and selectively reflects the fluorescent light FL be formed on the contact surface of the light-transmissive section 51X with the refrigerant transport member 12, as illustrated in FIG. 12.

The refrigerant transport member 12 is provided with the opening 12H at the position corresponding to the light emitting section (the irradiated position with the excitation light EL) of the phosphor layer 11. Porous glass 15 is inserted to the opening 12H, for example.

It is to be noted that the opening 12H may be filled with, for example, the phosphor layer 11, as with the wavelength conversion element 1A illustrated in FIG. 4. In addition, although FIG. 12 illustrates an example in which the light-transmissive section 51X includes a flat-shaped member having substantially the same thickness and shape as the surrounding storage section 51, the light-transmissive section 51X may include, for example, a light-transmitting member having a lens shape, as with the light-transmissive section 22.

### 2-3. Modification Example 7

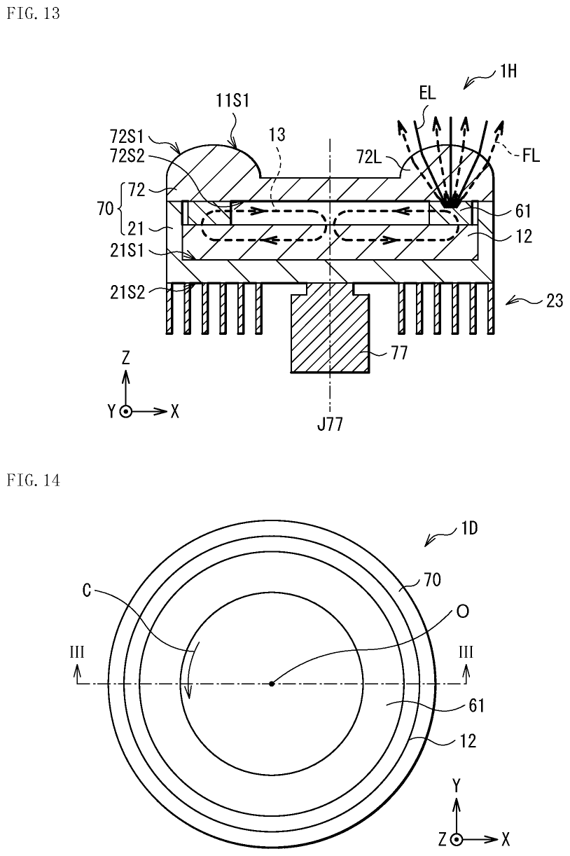

FIG. 13 schematically illustrates an example of a cross-sectional configuration of a wavelength conversion element (wavelength conversion element 1H) according to a modification example 7 of the present disclosure. FIG. 14 schematically illustrates a planar configuration of the wavelength conversion element 1H illustrated in FIG. 13. FIG. 13 illustrates a cross-sectional configuration taken along an line illustrated in FIG. 14. As with the embodiment or the like described above, this wavelength conversion element 1H is included in the light source module (light source module 100) of the projection display apparatus (projector 1000). The wavelength conversion element 1H according to the present modification example is a so-called reflective phosphor wheel that is rotatable around a rotation axis (e.g., axis J77).

In the present modification example, the phosphor layer 61 is continuously formed in the rotating circumferential direction (arrow C direction) of the refrigerant transport member 12 having a circular shape, for example, as illustrated in FIG. 14. In other words, a phosphor layer 61 is formed, for example, to have an annular shape.

A housing 70 is a wheel member. For example, a motor 77 is attached to the housing 70. The motor 77 is for rotating and driving the wavelength conversion element 1H at predetermined rotation speed. The motor 77 drives the wavelength conversion element 1H to rotate the phosphor layer 61 in the plane orthogonal to the radiation direction of the excitation light EL emitted from the light source section 110. This temporally changes (moves) the irradiated position of the wavelength conversion element 1H with the excitation light EL in the plane orthogonal to the radiation direction of the excitation light at the speed corresponding to the rotation speed.

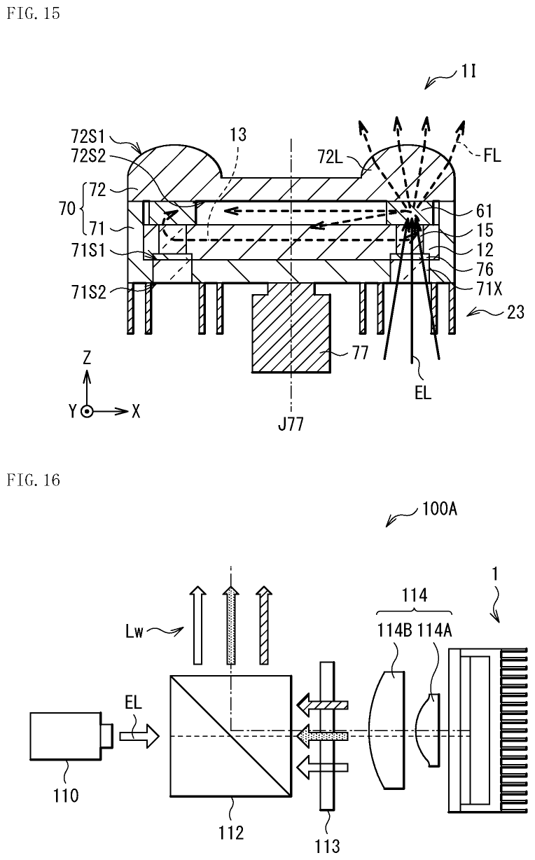

In the housing 70 according to the present modification example, a light-transmissive section 72 included in the front part includes, for example, a light-transmitting member having a lens shape, as with the embodiment described above. Specifically, the light-transmissive section 72 includes a light-transmitting member having a doughnut-shaped spherical surface to be opposed to the annular phosphor layer 61, as illustrated in FIG. 15.

In addition, the present technology is also applicable to a so-called transmissive phosphor wheel.

FIG. 15 schematically illustrates another example of a cross-sectional configuration of a wavelength conversion element (wavelength conversion element 1I) according to the modification example 7 of the present disclosure. This wavelength conversion element 1I is a so-called transmissive phosphor wheel in which the fluorescent light FL emitted from the phosphor layer 11 passes through the phosphor layer 11 and is extracted from the opposite surface (surface 72S1) to the surface (surface 71S2) irradiated with the excitation light EL.

In the wavelength conversion element 1I, at least a portion (a portion that receives the incident excitation light EL) of a storage section 71 included in the back part of the housing 70 includes a light-transmissive section 71X, as with the housing 50 of the modification example 6 described above. In addition, for example, it is preferable that an optical thin film 76 that transmits the excitation light EL and selectively reflects the fluorescent light FL be formed on the contact surface of the light-transmissive section 71X with the refrigerant transport member 12.

As described above, the present technology is also applicable to the transmissive wavelength conversion element 1G and the rotary wavelength conversion elements 1H and 1I. By applying the present technology to the transmissive wavelength conversion element 1G as with the modification example 6, an optical system for separation between the excitation light EL and the fluorescent light FL becomes unnecessary. This accordingly enables miniaturization, as compared with the reflective wavelength conversion element (e.g., the wavelength conversion elements 1 and 1A to 1F). In addition, by applying the present technology to the rotary wavelength conversion elements 1H and 1I as with the modification example 7, centrifugal force also contributes to the circulation of the refrigerant 13 in addition to the capillary force described above. It is therefore possible for the rotary wavelength conversion elements 1H and 1I described above to obtain higher cooling performance than that of a non-rotary wavelength conversion element (e.g., the wavelength conversion elements 1 and 1A to 1G described above).

### 3. Application Example

### Configuration Example of Light Source Module

FIG. 16 is an outline diagram illustrating an overall configuration of an example (light source module 100A) of the light source module 100 included, for example, in the projector 1000 described below. The light source module 100A includes the wavelength conversion element 1 (any of the wavelength conversion elements 1A to 1I described above), the light source section 110, a polarizing beam splitter (PBS) 112, a quarter-wave plate 113, and a condensing optical system 114. The respective members included in the light source module 100A described above are disposed on an optical path of light (combined light Lw) emitted from the wavelength conversion element 1 in the order of the condensing optical system 114, the quarter-wave plate 113, and the PBS 112 from the wavelength conversion element 1 side. The light source section 110 is disposed at a position opposed to one light incidence surface of the PBS 112 in the direction orthogonal to the optical path of the combined light Lw.

The light source section 110 includes a solid-state light emitting element that emits light having a predetermined wavelength. A semiconductor laser element that oscillates the excitation light EL (e.g., blue laser light having a wavelength of 445 nm or 455 nm) is used as a solid-state light emitting element. The linearly-polarized (S-polarized) excitation light EL is emitted from the light source section 110.

It is to be noted that, in a case where the light source section 110 includes a semiconductor laser element, the excitation light EL having predetermined output power may be obtained by one semiconductor laser element, but the excitation light EL having the predetermined output power may be obtained by combining the pieces of light outputted from a plurality of semiconductor laser elements. Further, the wavelength of the excitation light EL is not limited to the numeric value described above. Any wavelength may be used as long as the wavelength falls within the wavelength band of light that is referred to as blue light.

The PBS 112 is for separating the excitation light EL inputted from the light source section 110 and the combined light Lw inputted from the wavelength conversion element 1. Specifically, the PBS 112 reflects the excitation light EL inputted from the light source section 110 toward the quarter-wave plate 113. In addition, the PBS 112 transmits the combined light Lw that has been inputted from the wavelength conversion element 1 through the condensing optical system 114 and the quarter-wave plate 113. The transmitted combined light Lw is inputted to an illumination optical system 200 (described below).

The quarter-wave plate 113 is a phase difference element that causes incident light to have a phase difference of π/2. In a case where the incident light is linearly-polarized light, the linearly-polarized light is converted into circularly-polarized light. In a case where the incident light is circularly-polarized light, the circularly-polarized light is converted into linearly-polarized light. The linearly-polarized excitation light EL emitted from the polarizing beam splitter 112 is converted by the quarter-wave plate 113 into the circularly-polarized excitation light EL. In addition, the circularly-polarized excitation light component included in the combined light Lw emitted from the wavelength conversion element 1 is converted by the quarter-wave plate 113 into linearly-polarized light.

The condensing optical system 114 condenses the excitation light EL emitted from the quarter-wave plate 113 in a predetermined spot diameter and emits the condensed excitation light EL toward the wavelength conversion element 1. In addition, the condensing optical system 114 converts the combined light Lw emitted from the wavelength conversion element 1 into parallel light and emits the parallel light toward the quarter-wave plate 113. It is to be noted that the condensing optical system 114 may include, for example, one collimating lens or may have a configuration in which incident light is converted into parallel light by using a plurality of lenses.

It is to be noted that the configuration of an optical member that separates the excitation light EL inputted from the light source section 110 and the combined light Lw outputted from the wavelength conversion element 1 is not limited to that of the PBS 112. It is possible to use any optical member as long as the configuration thereof allows for the light separating operation described above.

### Configuration Example 2 of Light Source Module

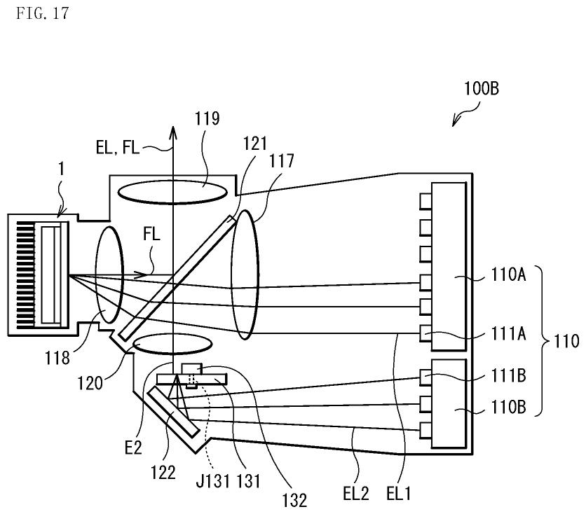

FIG. 17 is an outline diagram illustrating an overall configuration of another example (light source module 100B) of the light source module 100.

The light source module 100B includes the wavelength conversion element 1, a diffusion plate 131, the light source section 110 that emits excitation light or laser light, lenses 117 to 120, a dichroic mirror 121, and a reflecting mirror 122. The diffusion plate 131 is rotatably supported by a shaft J131 and rotated and driven, for example, by a motor 132. The light source section 110 includes a first laser group 110A and a second laser group 110B. A plurality of semiconductor laser elements 111A each of which oscillates excitation light (e.g., a wavelength of 445 nm or 455 nm) is arranged in the first laser group 110A. A plurality of semiconductor laser elements 111B each of which oscillates blue laser light (e.g., a wavelength of 465 nm) is arranged in the second laser group 110B. Here, for the sake of convenience, the excitation light that is oscillated from the first laser group 110A is defined as EL1 and blue laser light (that is simply referred to as blue light) that is oscillated from the second laser group 110B is defined as EL2.

In the light source module 100B, the wavelength conversion element 1 is disposed to input the excitation light EL1 to the phosphor layer 11. The excitation light EL1 has passed through the lens 117, the dichroic mirror 121, and the lens 118 in order from the first laser group 110A. The fluorescent light FL from the wavelength conversion element 1 is reflected by the dichroic mirror 121. After that, the fluorescent light FL passes through the lens 119 and travels to the outside. In other words, the fluorescent light FL travels to the illumination optical system 200 described below. The diffusion plate 131 diffuses the blue light EL2 that has passed through the reflecting mirror 122 from the second laser group 110B. The blue light EL2 diffused by the diffusion plate 131 passes through the lens 120 and the dichroic mirror 121. After that, the blue light EL2 passes through the lens 119 and travels to the outside. In other words, the blue light EL2 travels to the illumination optical system 200.

### Configuration Example 1 of Projector

FIG. 18 is an outline diagram illustrating an overall configuration of the projector 1000 including the light source module 100 (the light source modules 100A and 100B described above) illustrated in FIG. 16 or the like as a light source optical system. It is to be noted that the following gives description by exemplifying a reflective 3LCD projector that performs light modulation by a reflective liquid crystal panel (LCD).

As illustrated in FIG. 18, the projector 1000 includes the light source module 100 described above, the illumination optical system 200, an image forming section 300, and a projecting optical system 400 (projection optical system) in order.

The illumination optical system 200 includes, for example, a fly eye lens 210 (210A and 210B), a polarization conversion element 220, a lens 230, dichroic mirrors 240A and 240B, reflecting mirrors 250A and 250B, lenses 260A and 260B, a dichroic mirror 270, and polarizing plates 280A to 280C from positions closer to the light source module 100.

The fly eye lens 210 (210A and 210B) achieves uniform distribution of illumination of white light from the light source module 100. The polarization conversion element 220 functions to align the polarization axis of incident light with a predetermined direction. For example, light other than P-polarized light is converted into P-polarized light. The lens 230 condenses light from the polarization conversion element 220 toward the dichroic mirrors 240A and 240B. Each of the dichroic mirrors 240A and 240B selectively reflects light in a predetermined wavelength range and selectively transmits the pieces of light in the other wavelength ranges. For example, the dichroic mirror 240A mainly reflects red light in the direction of the reflecting mirror 250A. In addition, the dichroic mirror 240B mainly reflects blue light in the direction of the reflecting mirror 250B. Mainly green light thus passes through both of the dichroic mirrors 240A and 240B and travels to a reflective polarizing plate 310C (described below) of the image forming section 300. The reflecting mirror 250A reflects light (mainly red light) from the dichroic mirror 240A toward the lens 260A and the reflecting mirror 250B reflects light (mainly blue light) from the dichroic mirror 240B toward the lens 260B. The lens 260A transmits light (mainly red light) from the reflecting mirror 250A and condenses the light on the dichroic mirror 270. The lens 260B transmits light (mainly blue light) from the reflecting mirror 250B and condenses the light on the dichroic mirror 270. The dichroic mirror 270 selectively reflects green light and selectively transmits the pieces of light in the other wavelength ranges. Here, the dichroic mirror 270 transmits the red light component of light from the lens 260A. In a case where the light from the lens 260A includes a green light component, the green light component is reflected toward the polarizing plate 280C. Each of the polarizing plates 280A to 280C includes a polarizer having a polarization axis in a predetermined direction. For example, in a case where light is converted into P-polarized light by the polarization conversion element 220, each of the polarizing plates 280A to 280C transmits the P-polarized light and reflects S-polarized light.

The image forming section 300 includes reflective polarizing plates 310A to 310C, reflective liquid crystal panels 320A to 320C (light modulation elements), and a dichroic prism 330.

The reflective polarizing plates 310A to 310C respectively transmit pieces of light (e.g., pieces of P-polarized light) having the same polarization axes as the polarization axes of the pieces of polarized light from the polarizing plates 280A to 280C and reflect pieces of light (pieces of S-polarized light) having the other polarization axes. Specifically, the reflective polarizing plate 310A transmits P-polarized red light from the polarizing plate 280A in the direction of the reflective liquid crystal panel 320A. The reflective polarizing plate 310B transmits P-polarized blue light from the polarizing plate 280B in the direction of the reflective liquid crystal panel 320B. The reflective polarizing plate 310C transmits P-polarized green light from the polarizing plate 280C in the direction of the reflective liquid crystal panel 320C. In addition, the P-polarized green light that has passed through both of the dichroic mirrors 240A and 240B and has been inputted to the reflective polarizing plate 310C passes through the reflective polarizing plate 310C as it is and is inputted to the dichroic prism 330. Further, the reflective polarizing plate 310A reflects S-polarized red light from the reflective liquid crystal panel 320A and inputs the S-polarized red light to the dichroic prism 330. The reflective polarizing plate 310B reflects S-polarized blue light from the reflective liquid crystal panel 320B and inputs the S-polarized blue light to the dichroic prism 330. The reflective polarizing plate 310C reflects S-polarized green light from the reflective liquid crystal panel 320C and inputs the S-polarized green light to the dichroic prism 330.

The reflective liquid crystal panels 320A to 320C perform spatial modulation on red light, blue light, or green light, respectively.

The dichroic prism 330 combines red light, blue light, and green light that are inputted thereto and emits the combined light toward the projecting optical system 400.

The projecting optical system 400 includes lenses L410 to L450 and a mirror M400. The projecting optical system 400 enlarges light outputted from the image forming section 300 to project it onto a screen 460 or the like.

### Operations of Light Source Module and Projector

Next, an operation of the projector 1000 including the light source module 100 is described with reference to FIGS. 16 and 18.

First, the excitation light EL is oscillated from the light source section 110 toward the PBS. The excitation light EL is reflected by the PBS 112 and then passes through the quarter-wave plate 113 and the condensing optical system 114 in this order. The wavelength conversion element 1 is irradiated with the excitation light EL.

In the wavelength conversion element 1, a portion of the excitation light EL (blue light) is absorbed in the phosphor layer 11 and is converted into light (fluorescent light FL; yellow light) in a predetermined wavelength band. The fluorescent light FL emitted from the phosphor layer 11 is diffused along with a portion of the excitation light EL that is not absorbed in the phosphor layer 11 and is reflected toward the condensing optical system 114 side. As a result, the fluorescent light FL and a portion of the excitation light EL are combined to generate white light in the wavelength conversion element 1. This white light (combined light Lw) is outputted toward the condensing optical system 114.

After that, the combined light Lw passes through the condensing optical system 114, the quarter-wave plate 113, and the PBS 112 and is inputted to the illumination optical system 200.

The combined light Lw (white light) inputted from the light source module 100 (light source module 100A) sequentially passes through the fly eye lens 210 (210A and 210B), the polarization conversion element 220, and the lens 230 and then reaches the dichroic mirrors 240A and 240B.

The dichroic mirror 240A mainly reflects red light. This red light sequentially passes through the reflecting mirror 250A, the lens 260A, the dichroic mirror 270, the polarizing plate 280A, and the reflective polarizing plate 310A and reaches the reflective liquid crystal panel 320A. This red light is subjected to spatial modulation at the reflective liquid crystal panel 320A and then reflected by the reflective polarizing plate 310A to be inputted to the dichroic prism 330. It is to be noted that, in a case where light reflected toward the reflecting mirror 250A by the dichroic mirror 240A includes a green light component, the green light component is reflected by the dichroic mirror 270 and sequentially passes through the polarizing plate 280C and the reflective polarizing plate 310C to reach the reflective liquid crystal panel 320C. The dichroic mirror 240B mainly reflects blue light. The blue light is inputted to the dichroic prism 330 through a similar process. The green light that has passed through the dichroic mirrors 240A and 240B is also inputted to the dichroic prism 330.

The red light, the blue light, and the green light inputted to the dichroic prism 330 are combined and then emitted toward the projecting optical system 400 as image light. The projecting optical system 400 enlarges image light from the image forming section 300 to project it onto a screen 500 or the like.

### Configuration Example 2 of Projector

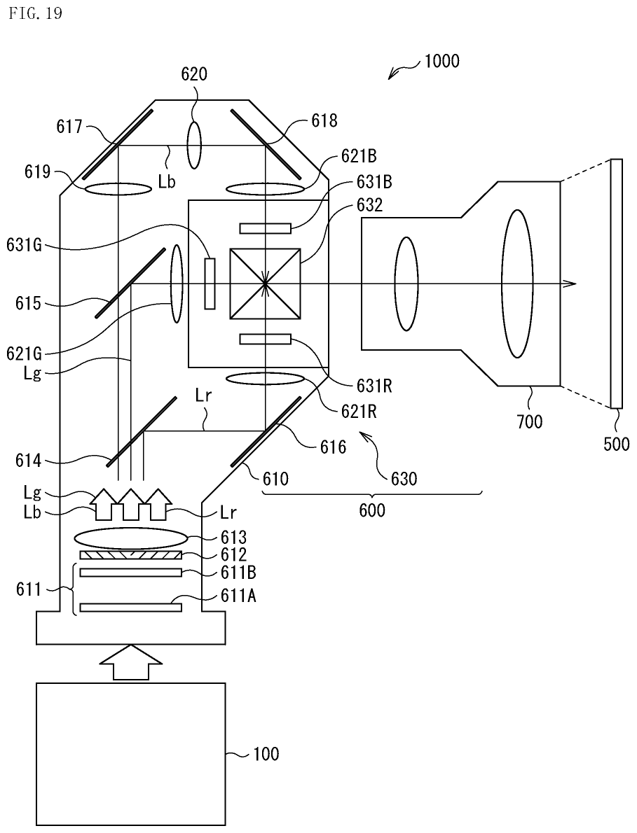

FIG. 19 is an outline diagram illustrating an example of a configuration of a transmissive 3LCD projection display apparatus (projector 1000) that performs light modulation by a transmissive liquid crystal panel. This projector 1000 includes, for example, the light source module 100, an image generation system 600 including an illumination optical system 610 and an image generation section 630, and a projection optical system 700.

The illumination optical system 610 includes, for example, an integrator element 611, a polarization conversion element 612, and a condensing lens 613. The integrator element 611 includes a first fly eye lens 611A including a plurality of microlenses arranged two-dimensionally and a second fly eye lens 611B including a plurality of microlenses arranged in association with the microlenses one by one.

Light (parallel light) inputted to the integrator element 611 from the light source module 100 is divided into a plurality of light fluxes by the microlenses of the first fly eye lens 611A. Images of the light fluxes are formed on the respective corresponding microlenses of the second fly eye lens 611B. The microlenses of the second fly eye lens 611B each function as a secondary light source and irradiate the polarization conversion element 612 with a plurality of pieces of parallel light having uniform luminance as incident light.

The integrator element 611 has a function of arranging the incident light with which the polarization conversion element 612 is irradiated from the light source module 100 as light having uniform luminance distribution as a whole.

The polarization conversion element 612 has a function of causing the incident light inputted through the integrator element 611 or the like to have a uniform polarization state. For example, this polarization conversion element 612 outputs output light including blue light Lb, green light Lg, and red light Lr through a lens and the like disposed on the output side of the light source module 100.

The illumination optical system 610 further includes a dichroic mirror 614 and a dichroic mirror 615, a mirror 616, a mirror 617 and a mirror 618, a relay lens 619 and a relay lens 620, a field lens 621R, a field lens 621G, and a field lens 621B, liquid crystal panels 631R, 631G, and 631B serving as the image generation section 630, and a dichroic prism 632.

The dichroic mirror 614 and the dichroic mirror 615 each have the property of selectively reflecting color light in a predetermined wavelength range and transmitting the pieces of light in the other wavelength ranges. For example, the dichroic mirror 614 selectively reflects the red light Lr. The dichroic mirror 615 selectively reflects the green light Lg of the green light Lg and the blue light Lb that have passed through the dichroic mirror 614. The remaining blue light Lb passes through the dichroic mirror 615. This separates light (e.g., white combined light Lw) outputted from the light source module 100 into a plurality of pieces of color light that is different in color.

The separated red light Lr is reflected by the mirror 616 and collimated by passing through the field lens 621R. After that, the red light Lr is inputted to the liquid crystal panel 631R for modulating red light. The green light Lg is collimated by passing through the field lens 621G and then inputted to the liquid crystal panel 631G for modulating green light. The blue light Lb is reflected by the mirror 617 through the relay lens 619 and further reflected by the mirror 618 through the relay lens 620. The blue light Lb reflected by the mirror 618 is collimated by passing through the field lens 621B and then inputted to the liquid crystal panel 631B for modulating the blue light Lb.

The liquid crystal panels 631R, 631G, and 631B are electrically coupled to an unillustrated signal source (e.g., PC or the like) that supplies an image signal including image information. The liquid crystal panels 631R, 631G, and 631B modulate incident light on a pixel-by-pixel basis on the basis of the supplied image signals of the respective colors and generate a red image, a green image, and a blue image, respectively. The pieces of modulated light (formed images) of the respective colors are combined by being inputted to the dichroic prism 632. The dichroic prism 632 superimposes and combines the pieces of light of the respective colors inputted from the three directions and outputs the combined light toward the projection optical system 700.

The projection optical system 700 includes, for example, a plurality of lenses and the like. The projection optical system 700 enlarges light outputted from the image generation system 600 and projects the light onto the screen 500.

Although the present disclosure has been described above with reference to the embodiment and the modification examples 1 to 7, the present disclosure is not limited to the embodiment or the like described above. A variety of modifications are possible. For example, the material, thickness, and the like of each layer that have been described in the embodiment described above are merely examples, but this is not limitative. Another material and thickness may be adopted.

In addition, in the embodiment or the like described above, the housing (e.g., the housing 20) stores the phosphor layer 11, the refrigerant transport member 12, and the refrigerant 13. The phosphor layer 11 and the refrigerant transport member 12 are disposed to cause the phosphor layer 11 to be opposed to the light-transmissive section 22 side, for example, in FIG. 1, but this is not limitative.

Further, in the embodiment or the like described above, FIG. 1 or the like illustrates an example in which the surface (e.g., the surface 22S2), of each of the light-transmissive sections 22, 32, and 72, right opposed to the phosphor layer 11 has a planar shape. However, the surface, of each of the light-transmissive sections 22, 32, and 72, right opposed to the phosphor layer 11 does not necessarily have to have a planar shape.

Further, although the modification examples 1 to 7 described above have been described as modification examples of the embodiment 1, the modification examples 1 to 7 may be combined with each other.

Still further, a configuration other than the light source modules 100A and 100B described above may be used as the light source module according to the present technology. Further, an apparatus other than the projector 1000 described above may be configured as the projection display apparatus. For example, the example has been described in which a reflective liquid crystal panel or a transmissive liquid crystal panel is used as a light modulation element in the projector 1000 described above, but the present technology may also be applied to a projector including a digital micromirror device (DMD: Digital Micro-mirror Device) or the like.

Further, in the present technology, the wavelength conversion element 1, the light source module 100, and the like according to the present technology may be included in an apparatus that is not the projection display apparatus. For example, the light source module 100 according to the present disclosure may be used for illumination application and is applicable, for example, to a head lamp for an automobile and a light source for lighting up.

It is to be noted that the present technology may also have configurations as follows. According to the present technology having the following configurations, the output light outputted from the phosphor layer is refracted by the output surface of the light-transmissive section, thus being able to be extracted as output light with a small etendue. This makes it possible to provide a wavelength conversion element with high light utilization efficiency. It is to be noted that the effects described here are not necessarily limited, but any of effects described in the present disclosure may be included.

[1]

A wavelength conversion element including:
a phosphor layer including a plurality of phosphor particles;
a refrigerant that cools the phosphor layer;
a storage section that stores the phosphor layer and the refrigerant; and
a light-transmissive section that seals the storage section in combination with the storage section, and controls an output direction of output light outputted from the phosphor layer.
   [2]

The wavelength conversion element according to [1], further including
a refrigerant transport member provided in contact with the phosphor layer, the refrigerant transport member circulating the refrigerant, in which
the refrigerant transport member is stored in the storage section, along with the phosphor layer and the refrigerant.
   [3]

The wavelength conversion element according to [1] or [2], in which the phosphor layer has a gap therein.

[4]

The wavelength conversion element according to any one of [1] to [3], in which the phosphor layer includes two or more layers.

[5]

The wavelength conversion element according to any one of [1] to [4], in which the storage section and the light-transmissive section are bonded together.

[6]

The wavelength conversion element according to any one of [1] to [5], in which the light-transmissive section includes a planoconvex lens.

[7]

The wavelength conversion element according to any one of [1] to [5], in which the light-transmissive section includes a Fresnel lens.

[8]

The wavelength conversion element according to any one of [1] to [5], in which the light-transmissive section includes a meta-lens.

[9]

The wavelength conversion element according to any one of [1] to [8], in which a portion of the light-transmissive section serves as a reflection surface.

[10]

The wavelength conversion element according to any one of [1] to [9], in which the phosphor layer includes a plurality of types of phosphor particles that emit light of different wavelengths.

[11]

The wavelength conversion element according to any one of [1] to [10], in which the phosphor layer includes a quantum dot.

[12]

The wavelength conversion element according to any one of [1] to [11], in which an opposed surface of the storage section has light reflectivity, the opposed surface being opposed to the light-transmissive section across the phosphor layer.

[13]

The wavelength conversion element according to any one of [1] to [12], in which an opposed surface of the storage section has light transmissivity, the opposed surface being opposed to the light-transmissive section across the phosphor layer.

[14]

The wavelength conversion element according to any one of [1] to [13], in which the phosphor layer is directly cooled by latent heat caused by vaporization of the refrigerant.

[15]

The wavelength conversion element according to any one of [2] to [14], in which

the refrigerant is circulated by capillary force generated in the phosphor layer and capillary force generated in the refrigerant transport member, and

the capillary force in the phosphor layer is greater than the capillary force in the refrigerant transport member.

[16]

The wavelength conversion element according to any one of [2] to [15], in which, in a case where the phosphor layer and the refrigerant transport member are used with respective surfaces of the phosphor layer and the refrigerant transport member standing upright, capillary force (P) in the refrigerant transport member satisfies the following expression (1):

(Expression 1) P≥hydraulic head difference R₀(mmH₂O) (1),

where R₀ is a distance from a light emitting section in the phosphor layer to an inner side wall of the storage section.

The wavelength conversion element according to any one of [1] to [16], in which the storage section further includes a heat dissipation member on a back surface.

The wavelength conversion element according to any one of [1] to [17], in which the storage section includes a rotatable wheel member, and the phosphor layer has an annular shape.

This application claims the priority on the basis of Japanese Patent Application No. 2019-127473 filed with Japan Patent Office on Jul. 9, 2019, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A wavelength conversion element, comprising:
a phosphor layer including a plurality of phosphor particles;
a refrigerant that cools the phosphor layer;
a storage section that stores the phosphor layer and the refrigerant; and
a light-transmissive section that seals the storage section in combination with the storage section, and controls an output direction of output light outputted from the phosphor layer.

2. The wavelength conversion element according to claim 1, further comprising
a refrigerant transport member provided in contact with the phosphor layer, the refrigerant transport member circulating the refrigerant, wherein
the refrigerant transport member is stored in the storage section, along with the phosphor layer and the refrigerant.

3. The wavelength conversion element according to claim 1, wherein the phosphor layer has a gap therein.

4. The wavelength conversion element according to claim 1, wherein the phosphor layer includes two or more layers.

5. The wavelength conversion element according to claim 1, wherein the storage section and the light-transmissive section are bonded together.

6. The wavelength conversion element according to claim 1, wherein the light-transmissive section comprises a planoconvex lens.

7. The wavelength conversion element according to claim 1, wherein the light-transmissive section comprises a Fresnel lens.

8. The wavelength conversion element according to claim 1, wherein the light-transmissive section comprises a meta-lens.

9. The wavelength conversion element according to claim 1, wherein a portion of the light-transmissive section serves as a reflection surface.

10. The wavelength conversion element according to claim 1, wherein the phosphor layer includes a plurality of types of phosphor particles that emit light of different wavelengths.

11. The wavelength conversion element according to claim 1, wherein the phosphor layer includes a quantum dot.

12. The wavelength conversion element according to claim 1, wherein an opposed surface of the storage section has light reflectivity, the opposed surface being opposed to the light-transmissive section across the phosphor layer.

13. The wavelength conversion element according to claim 1, wherein an opposed surface of the storage section has light transmissivity, the opposed surface being opposed to the light-transmissive section across the phosphor layer.

14. The wavelength conversion element according to claim 1, wherein the phosphor layer is directly cooled by latent heat caused by vaporization of the refrigerant.

15. The wavelength conversion element according to claim 2, wherein
the refrigerant is circulated by capillary force generated in the phosphor layer and capillary force generated in the refrigerant transport member, and
the capillary force in the phosphor layer is greater than the capillary force in the refrigerant transport member.

16. The wavelength conversion element according to claim 2, wherein, in a case where the phosphor layer and the refrigerant transport member are used with respective surfaces of the phosphor layer and the refrigerant transport member standing upright, capillary force (P) in the refrigerant transport member satisfies the following expression (1):
(Expression 1) P≥hydraulic head difference R₀(mmH₂O) (1),
where R₀ is a distance from a light emitting section in the phosphor layer to an inner side wall of the storage section.

17. The wavelength conversion element according to claim 1, wherein the storage section further includes a heat dissipation member on a back surface.

18. The wavelength conversion element according to claim 1, wherein the storage section comprises a rotatable wheel member, and the phosphor layer has an annular shape.
